(19) United States
(12) Patent Application Publication
(10) Pub. No.: US 2025/0321447 A1
(43) Pub. Date: Oct. 16, 2025

(54) DISPLAY PANEL

(71) Applicant: AUO Corporation, Hsinchu City (TW)

(72) Inventors: Jia-Hong Wang, Hsinchu City (TW); Yi-Wen Lin, Hsinchu City (TW); Ya-Ling Hsu, Hsinchu City (TW); Chen-Hsien Liao, Hsinchu City (TW)

(73) Assignee: AUO Corporation, Hsinchu City (TW)

(21) Appl. No.: 18/954,337

(22) Filed: Nov. 20, 2024

(30) Foreign Application Priority Data
Apr. 10, 2024 (TW) 113113417

(51) Int. Cl. G02F 1/13357; G02F 1/1339; H01L 25/075; H01L 33/62; H05K 1/18

(52) U.S. Cl. CPC G02F 1/133603; G02F 1/1339; H01L 25/0753; H05K 1/189; H10H 20/857; H05K 2201/10136

(57) ABSTRACT

A display panel includes a first substrate, a first circuit structure, a second circuit structure, a liquid crystal layer, a light-emitting diode module (LED module), a sealant layer and a second substrate. The first circuit structure and the second circuit structure are respectively disposed on the first surface and the second surface of the first substrate. The liquid crystal layer is located on the first circuit structure. The LED module includes a flexible circuit board and a light-emitting diode (LED). The flexible circuit board is connected to the second circuit structure and is bent from the second surface of the first substrate to above the first surface of the first substrate. The LED is disposed on the flexible circuit board located over the first surface of the first substrate. The sealant layer surrounds the liquid crystal layer and covers the LED.

### CROSS-REFERENCE TO RELATED APPLICATION

This application claims the priority benefit of Taiwan application serial no. 113113417, filed on Apr. 10, 2024. The entirety of the above-mentioned patent application is hereby incorporated by reference herein and made a part of this specification.

### BACKGROUND

### Technical Field

The present invention relates to a display panel.

### Description of Related Art

Light-emitting diode (LED) is a type of electroluminescent semiconductor device that has advantages such as high efficiency, long lifespan, durability, fast response speed, and high reliability. In common liquid crystal display devices, LEDs are set in the backlight module and used as light sources. The light emitted by the LEDs passes through the liquid crystal panel, and the liquid crystal panel controls whether the light passes through or not, thereby displaying images.

With the advancement of technology, the size of LEDs has gradually decreased, and many manufacturers are dedicated to developing display devices that directly use micro-LEDs to display images. However, how to effectively combine micro-LEDs with liquid crystal panels is still a problem that many researchers need to overcome.

### SUMMARY

The present invention provides a display panel that has the advantage of improving production yield.

At least one embodiment of the present invention provides a display panel, including a first substrate, a first circuit structure, a second circuit structure, a liquid crystal layer, an LED module, a sealant layer, and a second substrate. The first substrate has a first surface and a second surface opposite to the first surface. The first circuit structure is disposed on the first surface of the first substrate. The second circuit structure is disposed on the second surface of the first substrate. The liquid crystal layer is located on the first circuit structure. The LED module includes a flexible circuit board and an LED. The flexible circuit board is connected to the second circuit structure and bends from the second surface of the first substrate to above the first surface of the first substrate. The LED is disposed on the flexible circuit board located on the first surface of the first substrate and is electrically connected to the flexible circuit board. The sealant layer surrounds the liquid crystal layer and covers the LED. The second substrate overlaps the first substrate, and the first circuit structure, the sealant layer, the liquid crystal layer, and the LED are located between the first substrate and the second substrate.

If the LED is designed to be directly bonded to the circuit structure on the first substrate, testing and repairing of the LED can only be performed after bonding the LED to the circuit structure. In the embodiments of the present invention, the LED in the LED module may be tested before connecting the flexible circuit board to the second circuit structure, thereby reducing the difficulty of testing and repairing the LED, and consequently improving the production yield of the display panel. Moreover, since the first circuit structure and the second circuit structure are disposed on the first surface and the second surface of the first substrate respectively, the circuit layout space can be utilized more effectively.

### BRIEF DESCRIPTION OF THE DRAWINGS

FIGS. 1A, 1B, 2A, 2B, 3A, 3B, 4A, 4B, 5A and 5B are schematic views of various stages of a manufacturing method of a display panel according to an embodiment of the present invention.

FIG. 6 is a schematic bottom view of a display panel in accordance with an embodiment of the present invention.

FIG. 7 is a schematic bottom view of a display panel in accordance with another embodiment of the present invention.

FIG. 8 is a schematic top view of an LED module and a first alignment mark located beneath it in accordance with an embodiment of the present invention.

FIG. 9 is a schematic top view of a display panel in accordance with yet another embodiment of the present invention.

FIG. 10 is a schematic cross-sectional view of a display panel in accordance with another embodiment of the present invention.

FIG. 11 is a schematic bottom view of a display panel in accordance with yet another embodiment of the present invention.

FIG. 12 is a schematic cross-sectional view of a display panel in accordance with another embodiment of the present invention.

### DESCRIPTION OF THE EMBODIMENTS

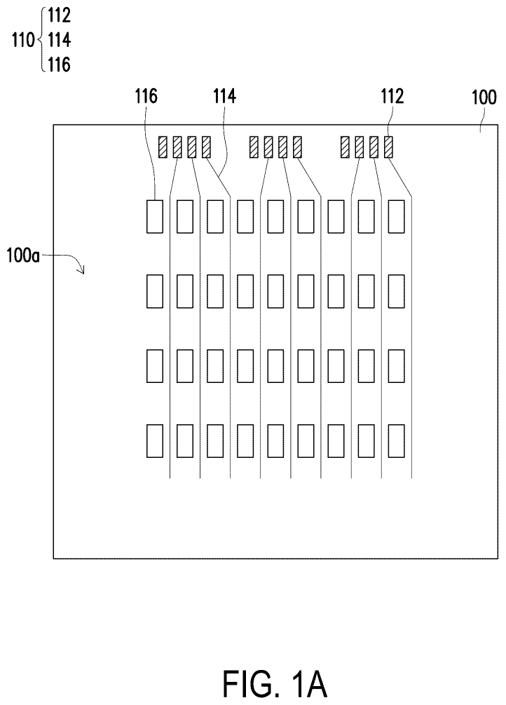

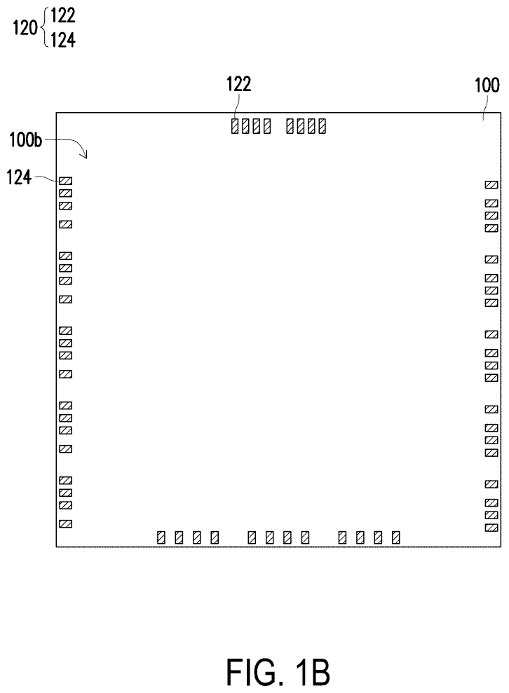

FIGS. 1A, 1B, 2A, 2B, 3A, 3B, 4A, 4B, 5A and 5B are schematic diagrams of various stages in a manufacturing method of a display panel 10 in accordance with an embodiment of the present invention. FIG. 1A is a schematic top view of a first substrate 100, and FIG. 1B is a schematic bottom view of the first substrate 100. Referring to FIG. 1A and FIG. 1B, a first substrate 100, a first circuit structure 110, and a second circuit structure 120 are provided. The first circuit structure 110 and the second circuit structure 120 are located on the first surface 100a and the second surface 100b of the first substrate 100, respectively, where the first surface 100a is opposite to the second surface 100b. In some embodiments, the first substrate 100, the first circuit structure 110, and the second circuit structure 120 may together be referred to as a pixel array substrate or an active device array substrate.

The first substrate 100 may be, for example, a rigid substrate, and its material may be glass, quartz, organic polymer or non-transparent/reflective material (e.g., conductive material, metal, wafer, ceramic or other applicable materials) or other applicable materials. However, the present invention is not limited thereto. In other embodiments, the first substrate 100 may also be a flexible substrate or a stretchable substrate. For example, materials for the flexible substrate and the stretchable substrate include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU) or other suitable materials.

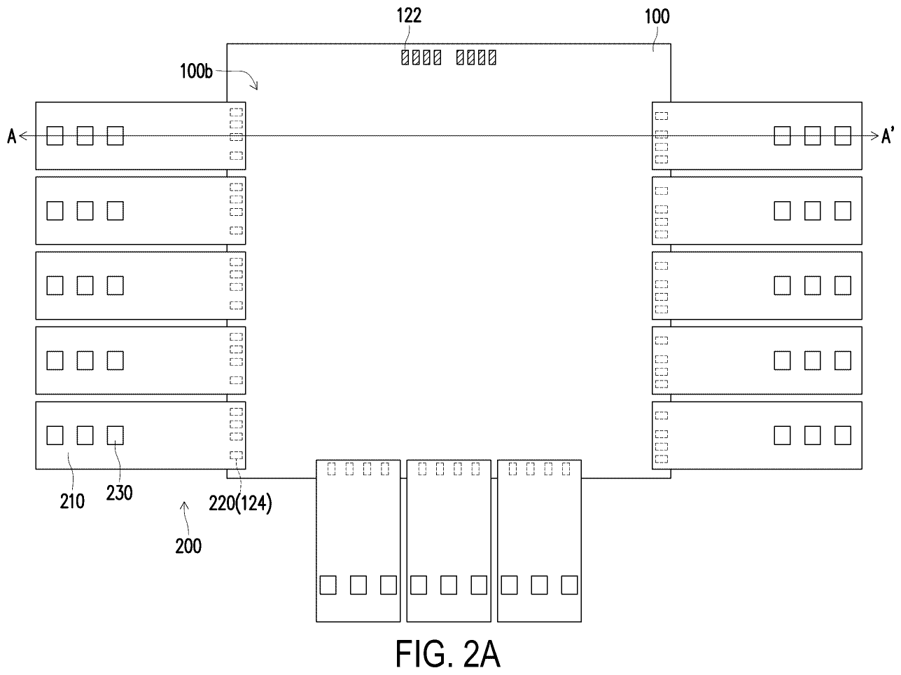

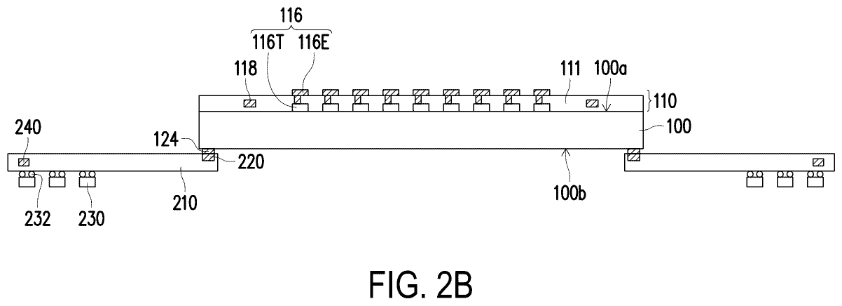

The first circuit structure 110 is disposed on the first surface 100a of the first substrate 100. The first circuit structure 110 may be, for example, composed of conductive layer(s) (e.g., including metal or other conductive materials), insulation layer(s), and semiconductor layer(s). In this embodiment, the first circuit structure 110 includes multiple first bonding pads 112, multiple first signal lines 114, and multiple pixel structures 116. The pixel structures 116 are arranged in an array, and each pixel structure 116 is electrically connected to a corresponding first bonding pad 112 through a corresponding first signal line 114. In some embodiments, the pixel structure 116 includes an active device 116T (refer to FIG. 2B) and a pixel electrode 116E (refer to FIG. 2B), where the active device 116T may be, for example, a thin film transistor. In some embodiments, an insulation structure 111 (refer to FIG. 2B) covers the active device 116T, and the pixel electrode 116E is disposed on the insulation structure 111. The pixel electrode 116E is electrically connected to the active device 116T through a conductive via in the insulation structure 111. In some embodiments, the insulation structure 111 includes a single layer or multiple layers of insulation. In some embodiments, the pixel structure 116 may also include passive devices (not shown).

In some embodiments, the first circuit structure 110 may also include other signal lines (not shown). For example, the first signal lines 114 may be data lines, and the first circuit structure 110 may also include multiple scan lines (not shown). In some embodiments, one or more first alignment marks 118 (refer to FIG. 2B) may be disposed over the first surface 100a and located in the insulation structure 111.

The second circuit structure 120 is disposed on the second surface 100b of the first substrate 100. The second circuit structure 120 may be, for example, composed of conductive layer(s) (e.g., including metal or other conductive materials). In some embodiments, the second circuit structure 120 may also include insulation layer(s). In this embodiment, the second circuit structure 120 includes multiple second bonding pads 122 and multiple connection pads 124. In some embodiments, the second circuit structure 120 may also include multiple signal lines (not shown), used to electrically connect each connection pad 124 to a corresponding second bonding pad 122 or other corresponding connection pads 124.

FIG. 2A is a schematic bottom view of the first substrate 100, and FIG. 2B is a schematic cross-sectional view along line A-A′ of FIG. 2A. Referring to FIG. 2A and FIG. 2B, multiple LED modules 200 are bonded to the second circuit structure 120. At least some of the connection pads 124 are bonded with the LED modules 200, and each LED module 200 is electrically connected to multiple corresponding connection pads 124.

In this embodiment, each LED module 200 includes a corresponding flexible circuit board 210 and one or more corresponding LEDs 230. The LEDs 230 may include, for example, red LEDs, green LEDs, and blue LEDs. The number and arrangement of LEDs 230 in each LED module 200 may be adjusted according to actual requirements.

The flexible circuit board 210 is connected to the second circuit structure 120. For example, multiple connection pads 220 in the flexible circuit board 210 are respectively electrically connected to corresponding connection pads 124 in the second circuit structure 120. The connection pads 220 and connection pads 124 may be connected to each other through, for example, silver paste, anisotropic conductive adhesive, solder, or other suitable conductive bonding materials.

In some embodiments, the flexible circuit board 210 may have one or more second alignment marks 240. The second alignment marks 240 are used in subsequent processes to align with corresponding first alignment marks 118 in the first circuit structure 110, thereby confirming that the LED modules 200 have been bonded to the correct positions.

The LEDs 230 are disposed on the side of the flexible circuit board 210 facing away from the first substrate 100. For example, the LEDs 230 are bonded to the flexible circuit board 210 through silver paste, anisotropic conductive adhesive, solder, or other suitable conductive bonding materials. The LEDs 230 may be any type of light-emitting diodes. For instance, the LEDs 230 may include a first semiconductor layer, a light-emitting layer, and a second semiconductor layer stacked sequentially, where one of the first semiconductor layer and the second semiconductor layer is an N-type doped semiconductor, and the other is a P-type doped semiconductor. Two electrodes are formed on the N-type doped semiconductor and the P-type doped semiconductor respectively, and are bonded to the flexible circuit board 210 through conductive connection structures 232, where the conductive connection structures 232 may include, for example, silver paste, anisotropic conductive adhesive, solder, or other suitable conductive bonding materials. In some embodiments, the flexible circuit board 210 may also include multiple signal lines (not shown) for electrically connecting the LEDs 230 to corresponding connection pads 220.

In some embodiments, before bonding the LED modules 200 to the second circuit structure 120, a lighting test of the LEDs 230 may be performed on the LED modules 200. Therefore, faulty LED modules 200 can be eliminated or repaired before the bonding process, thereby improving the production yield of the display panel 10.

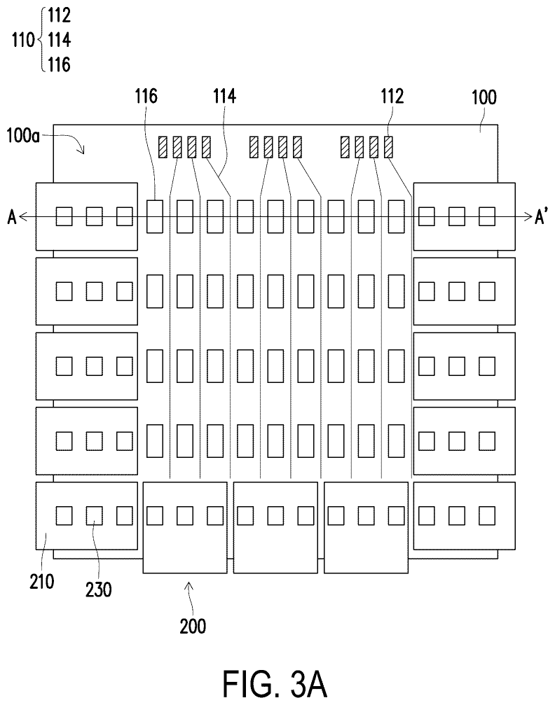

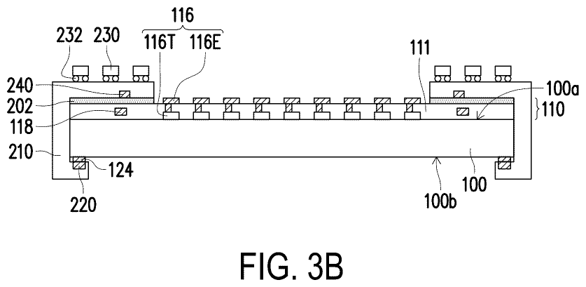

FIG. 3A is a schematic top view of the first substrate 100, and FIG. 3B is a schematic cross-sectional view along line A-A′ of FIG. 3A. Referring to FIG. 3A and FIG. 3B, the LED modules 200 are bent to above the first surface 100a of the first substrate 100. Specifically, the flexible circuit board 210 is bent, causing it to bend from the second surface 100b of the first substrate 110 to above the first surface 100a of the first substrate 100.

In some embodiments, an adhesive layer 202 may optionally be disposed between the flexible circuit board 210 and the first surface 100a of the first substrate 100. For example, the adhesive layer 202 is used to fix the flexible circuit board 210 on the first surface 100a of the first substrate 100 or on the first circuit structure 110. It should be noted that although the adhesive layer 202 is not shown in FIG. 2B, the adhesive layer 202 may be formed on the side of the flexible circuit board 210 facing away from the LEDs 230 or above the first surface 100a of the first substrate 110, either before or after bonding the flexible circuit board 210 to the second circuit structure 120.

Continuing to refer to FIG. 3A and FIG. 3B, after bending the LED modules 200 to above the first surface 100a of the first substrate 100, the LEDs 230 are disposed on the flexible circuit board 210 above the first surface 100a of the first substrate 100. In other words, after bending the LED modules 200, the LEDs 230 are located above the first surface 100a of the first substrate 100.

The second alignment marks 240 in the flexible circuit board 210 and the first alignment marks 118 in the first circuit structure 110 are used to confirm whether the LED modules 200 have been bent to the correct position. For example, through Automated Optical Inspection (AOI) or other suitable processes, the relative positions between the first alignment marks 118 and the second alignment marks 240 are checked to confirm whether the LED modules 200 and the first circuit structure 110 are correctly aligned. The first alignment marks 118 are adjacent to the second alignment marks 240.

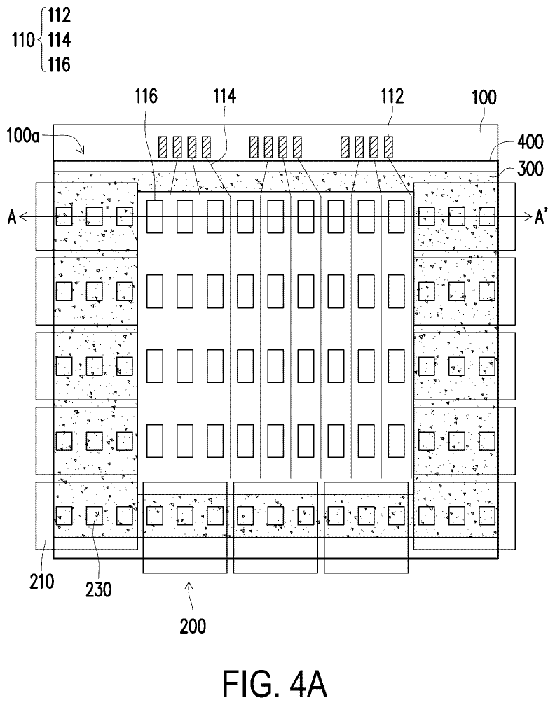

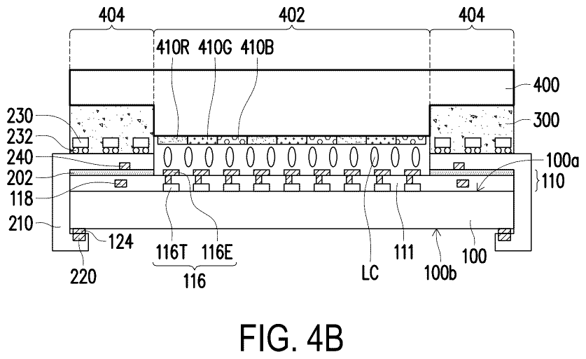

FIG. 4A is a schematic top view of the first substrate 100 and the second substrate 400. FIG. 4B is a schematic cross-sectional view along line A-A′ of FIG. 4A. Referring to FIG. 4A and FIG. 4B, the second substrate 400 is combined with the first substrate 100. The second substrate 400 overlaps the first substrate 100, and the second substrate 400 is attached to the first substrate 100 through the sealant layer 300. In some embodiments, the area of the second substrate 400 is smaller than the area of the first substrate 100, so that part of the first circuit structure 110 on the first substrate 100 may be exposed by the second substrate 400.

The sealant layer 300 covers the LEDs 230 of the LED modules 200. In this embodiment, the sealant layer 300 directly contacts the top surfaces and side surfaces of the LEDs 230, and fills between adjacent LEDs 230, but the invention is not limited thereto. In other embodiments, the LED modules 200 may also include an encapsulation glue (not shown) that encapsulates the LEDs 230, where the encapsulation glue separates the LEDs 230 from the sealant layer 300.

In some embodiments, the filter elements 410R, 410G, 410B are formed on the second substrate 400, therefore, the second substrate 400 may also be referred to as a filter element substrate. In other embodiments, the filter elements 410R, 410G, 410B are formed on the first substrate 100 and constitute a color filter on array (COA) structure. The filter elements 410R, 410G, 410B include filter elements of different colors. For example, the filter elements 410R, 410G, 410B are red filter elements, green filter elements, and blue filter elements, respectively. In some embodiments, a black matrix (not shown) may be included between the filter elements 410R, 410G, 410B of different colors, but the invention is not limited thereto. The filter elements 410R, 410G, 410B overlap the pixel structures 116.

The liquid crystal layer LC is injected between the first substrate 100 and the second substrate 400. The liquid crystal layer LC is located on the first circuit structure 110, and the pixel structures 116 overlap the liquid crystal layer LC. The sealant layer 300 surrounds the liquid crystal layer LC. The first circuit structure 110, the sealant layer 300, the liquid crystal layer LC, the filter elements 410R, 410G, 410B, the LEDs 230, and part of the flexible circuit board 210 are located between the first substrate 100 and the second substrate 400.

In this embodiment, the thickness of the liquid crystal layer LC is controlled by adjusting the thickness of the second substrate 400. Specifically, the second substrate 200 includes a liquid crystal area 402 overlapping the liquid crystal layer LC and an LED area 404 overlapping the LEDs 230. Through a grinding process, the thickness of the LED area 404 may be made smaller than the thickness of the liquid crystal area 402, thereby avoiding the problem of excessive thickness of the liquid crystal layer LC due to the height of the LEDs 230.

In this embodiment, by setting the LED display area constituted by the LEDs 230 around the periphery of the liquid crystal display area constituted by the pixel structures 116 and the liquid crystal layer LC, the display panel may have the advantage of a narrow bezel. In some embodiments, the pitch between adjacent pixel structures 116 is equal to the pitch between adjacent LEDs 230. In other words, the resolution of the liquid crystal display area including the pixel structures 116 is approximately equal to the resolution of the LED display area including the LEDs 230.

Additionally, in this embodiment, the LEDs 230 are disposed between the first substrate 100 and the second substrate 400, thereby making the light emitting type of the LED display area more similar to the light emitting type of the liquid crystal display area, improving the problem of discontinuity in the display image between the LED display area and the liquid crystal display area.

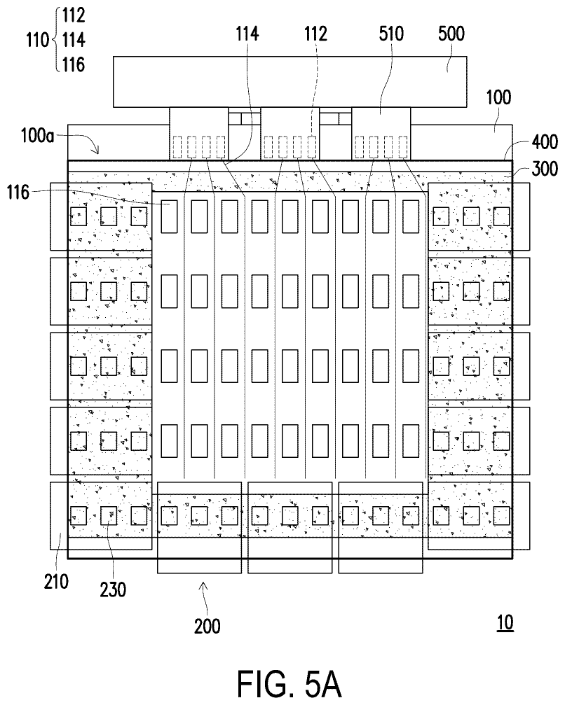

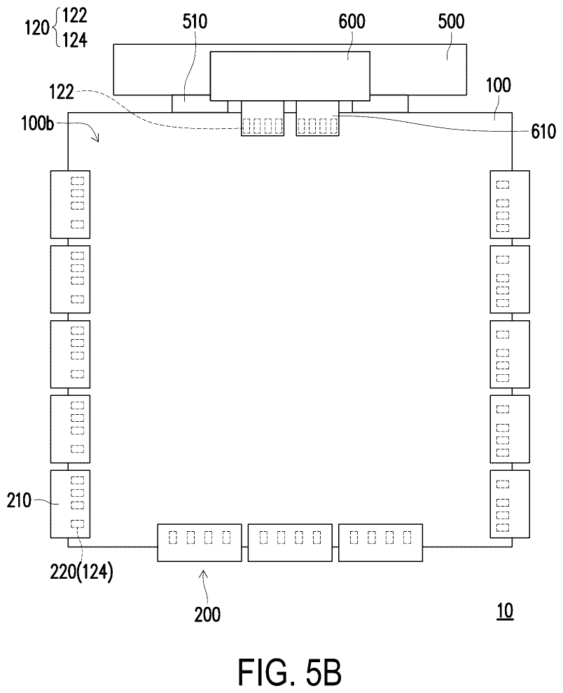

FIG. 5A is a schematic top view of the first substrate 100 and the second substrate 200, and FIG. 5B is a schematic bottom view of the first substrate 100. Referring to FIG. 5A first, the first system board 500 is electrically connected to the first bonding pads 112. For example, the first system board 500 is electrically connected to the first bonding pads 112 through multiple flexible circuit boards 510. The flexible circuit boards 510 may be bonded to the first bonding pads 112 through silver paste, anisotropic conductive adhesive, solder, or other suitable conductive bonding materials. In some embodiments, the first system board 500 may include one or more of a driving control circuit, a scanning control circuit, a multiplexing unit, an output storage circuit, a data driving circuit, a timing control circuit, and a voltage source conversion circuit.

The first system board 500 is electrically connected to the pixel structures 116 through the first bonding pad 112, and provides various control signals (such as operating voltage signals, control waveform timing, supply voltage sources, etc.) to the pixel structures 116 to control the display of the liquid crystal display area.

Next, referring to FIG. 5B, the second system board 600 is electrically connected to the second bonding pads 122. For example, the second system board 600 is electrically connected to the second bonding pads 122 through multiple flexible circuit boards 610. The first bonding pads 112 and the second bonding pads 122 are located on the first surface 100a and the second surface 100b of the first substrate 100 respectively, therefore, the first system board 500 and the second system board 600 are disposed on the first surface 100a and the second surface 100b of the first substrate 100 respectively.

In some embodiments, the second system board 600 may include one or more of a driving control circuit, an output storage circuit, a timing control circuit, and a voltage source conversion circuit.

The second system board 600 is electrically connected to the connection pads 220 of the flexible circuit board 210 through the second bonding pads 122, the wires (not shown) in the second circuit structure 120, and the connection pads 124, and provides various control signals (such as pulse width modulation (PWM) signals, operating current signals, etc.) to the LED module 200 to control the display of the LED display area.

In this embodiment, the first circuit structure 110 used for transmitting liquid crystal control signals to control the liquid crystal display area and the second circuit structure 120 used for transmitting LED control signals to control the LED display area are formed on the first surface 100a and the second surface 100b of the first substrate 100 respectively, thereby reducing the difficulty of circuit design. By distributing the circuits on different sides of the first substrate 100, the complexity of the circuits may be reduced, avoiding the problem of current instability in the LEDs 230 caused by interference between different circuits.

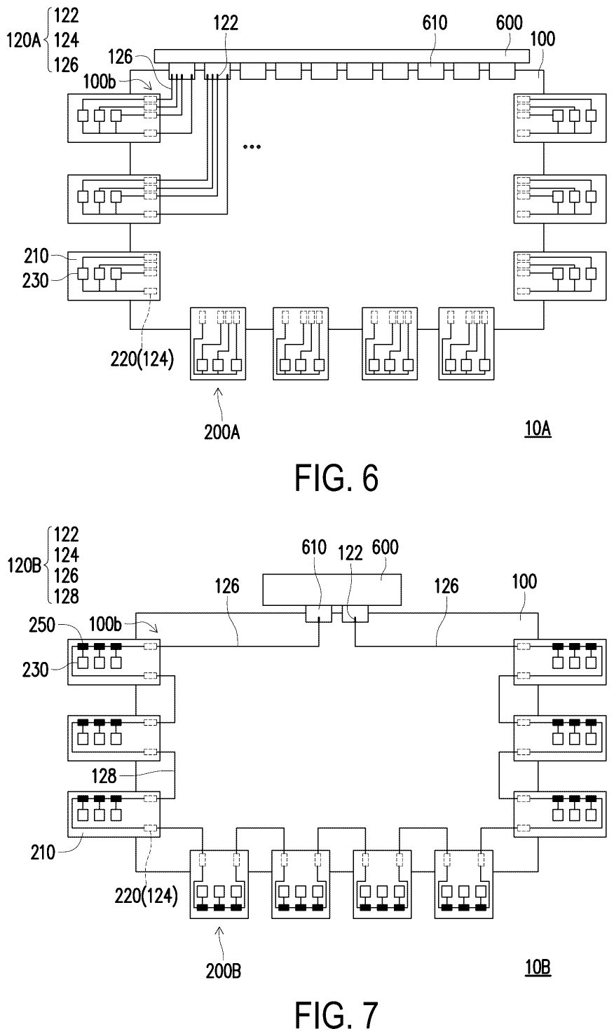

FIG. 6 is a schematic bottom view of a display panel 10A according to an embodiment of the invention. It should be noted herein that, in embodiments provided in FIG. 6, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

For the convenience of explanation, FIG. 6 is a schematic diagram without bending the LED module 200A. In fact, in the display panel 10A, the LED module 200A will be bent to the first surface of the first substrate 100, as shown in FIG. 5A and FIG. 5B.

Referring to FIG. 6, the second circuit structure 120A includes multiple second bonding pads 122, multiple connection pads 124, and multiple signal lines 126 (FIG. 6 only shows a portion of the signal lines 126).

The LED module 200 is bonded to the connection pads 124. The signal lines 126 electrically connect the second bonding pads 122 and the connection pads 124, thereby allowing the second system board 600 to transmit signals to the LED module 200 through the signal lines 126.

In this embodiment, the LED module 200 is a passive LED module 200. In other words, the LED module 200 does not include active devices for controlling the LEDs 230.

FIG. 7 is a schematic bottom view of a display panel 10B according to an embodiment of the invention. It should be noted herein that, in embodiments provided in FIG. 7, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

For the convenience of explanation, FIG. 7 is a schematic diagram without bending the LED module 200. In fact, in the display panel 10B, the LED module 200 will be bent to the first surface of the first substrate 100, as shown in FIG. 5A and FIG. 5B.

Referring to FIG. 7, each LED module 200 includes a flexible circuit board 210, one or more LEDs 230, and one or more integrated circuits (micro ICs) 250. The LEDs 230 and the micro ICs 250 are bonded to the flexible circuit board 210.

In this embodiment, the micro ICs 250 include control circuits for the LEDs 230, and the micro ICs 250 are electrically connected to the LEDs 230 through the flexible circuit board 210. By setting the micro ICs 250 in the LED module 200, the circuit density of the second circuit structure 120 may be reduced.

The second circuit structure 120 includes multiple second bonding pads 122, multiple connection pads 124, multiple signal lines 126, and multiple connection lines 128.

In this embodiment, multiple LED modules 200 are connected in series with each other. For example, each connection line 128 electrically connects the connection pads 220 of corresponding two adjacent ones of the LED modules 200. Through this design, the micro ICs 250 of different LED modules 200 may communicate through the connection lines 128, thereby executing the mapping of the LEDs 230. The signal lines 126 electrically connect the corresponding LED modules 200 to the second bonding pads 122, thereby electrically connecting the LED modules 200 to the second system board 600 through the second bonding pads 122.

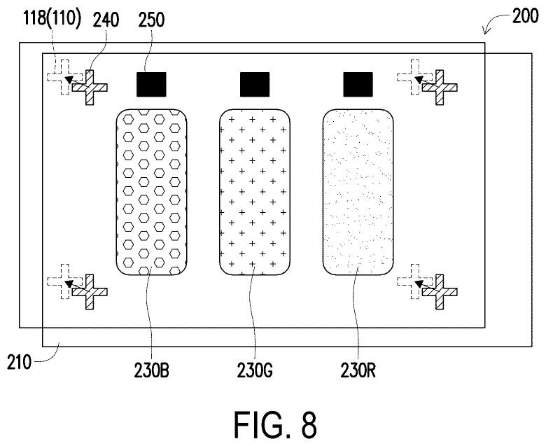

FIG. 8 is a schematic top view of an LED module 200 and a first alignment mark 118 located beneath it according to an embodiment of the invention. It should be noted herein that, in embodiments provided in FIG. 8, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 8, in this embodiment, the LED module 200 includes a red LED 230R, a green LED 230G, and a blue LED 230B. Each of the red LED 230R, green LED 230G, and blue LED 230B is disposed in correspondence with one micro IC 250.

The first alignment mark 118 and the second alignment mark 240 are designed in a cross shape, and are used to confirm whether the LED module 200 and the first circuit structure 110 located beneath it are correctly aligned.

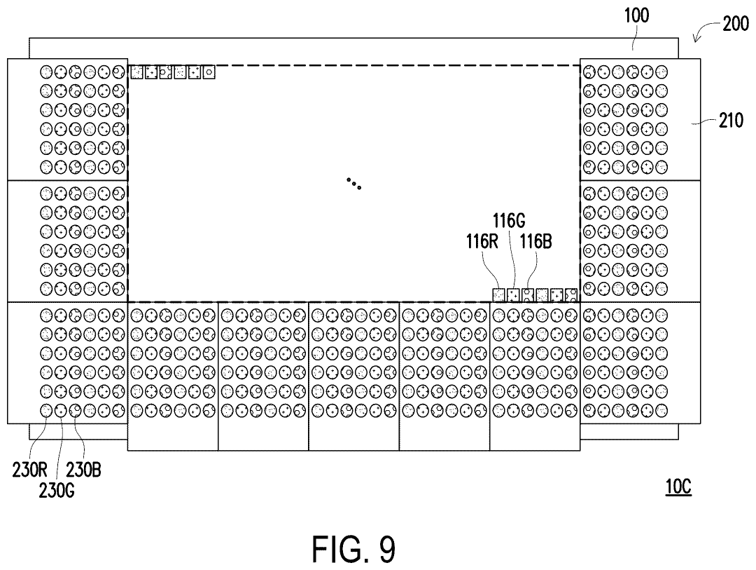

FIG. 9 is a schematic top view of a display panel 10C according to yet another embodiment of the invention. FIG. 9 illustrates the first substrate 100, the flexible circuit boards 210, the red subpixels 116R, the green subpixels 116G, the blue subpixels 116B, the red LEDs 230R, the green LEDs 230G, and the blue LEDs 230B of the display panel 10C, while omitting the illustration of other components. It should be noted herein that, in embodiments provided in FIG. 9, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 9, in this embodiment, each LED module 200 includes multiple red LEDs 230R, multiple green LEDs 230G, and multiple blue LEDs 230B. The number of red LEDs 230R, green LEDs 230G, and blue LEDs 230B in each LED module 200 may be adjusted according to actual requirements. The red LEDs 230R, green LEDs 230G, and blue LEDs 230B constitute an LED display area.

The liquid crystal display area includes multiple red subpixels 116R, multiple green subpixels 116G, and multiple blue subpixels 116B. The red subpixel 116R includes a red filter element (referring to FIG. 4B) and a pixel structure 116 (referring to FIG. 4B) overlapping with it, the green subpixel 116G includes a green filter element (referring to FIG. 4B) and a pixel structure 116 (referring to FIG. 4B) overlapping with it, and the blue subpixel 116B includes a blue filter element (referring to FIG. 4B) and a pixel structure 116 (referring to FIG. 4B) overlapping with it.

In this embodiment, the arrangement and sequence of the red subpixels 116R, green subpixels 116G, and blue subpixels 116B in the liquid crystal display area are similar to the arrangement and sequence of the red LEDs 230R, green LEDs 230G, and blue LEDs 230B in the LED display area. Therefore, the display shown in the LED display area may serve as an extension of the display shown in the liquid crystal display area, without causing issues of discontinuity in the display.

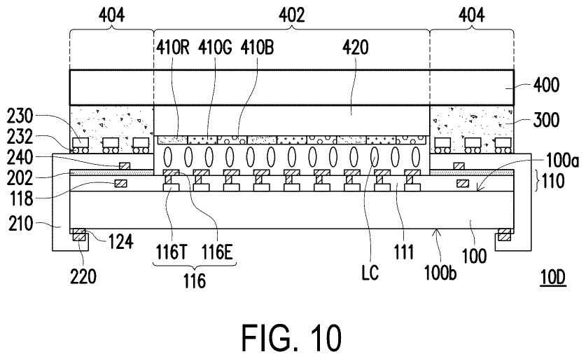

FIG. 10 is a schematic cross-sectional view of a display panel 10D according to another embodiment of the invention. It should be noted herein that, in embodiments provided in FIG. 10, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 10, the liquid crystal area 402 and the LED area 404 of the second substrate 400 have the same thickness. To avoid the problem of excessive thickness of the liquid crystal layer LC due to the height of the LED 230, a height augmentation layer 420 is disposed between the first substrate 100 and the second substrate 400. The height augmentation layer 420 overlaps with the liquid crystal layer LC in the normal direction of the first surface 100a of the first substrate 100, and does not overlap with the LED 230.

In this embodiment, the height augmentation layer 420 is located between the liquid crystal layer LC and the second substrate 400, but the invention is not limited thereto. In other embodiments, the height augmentation layer 420 may be located between the liquid crystal layer LC and the first substrate 100.

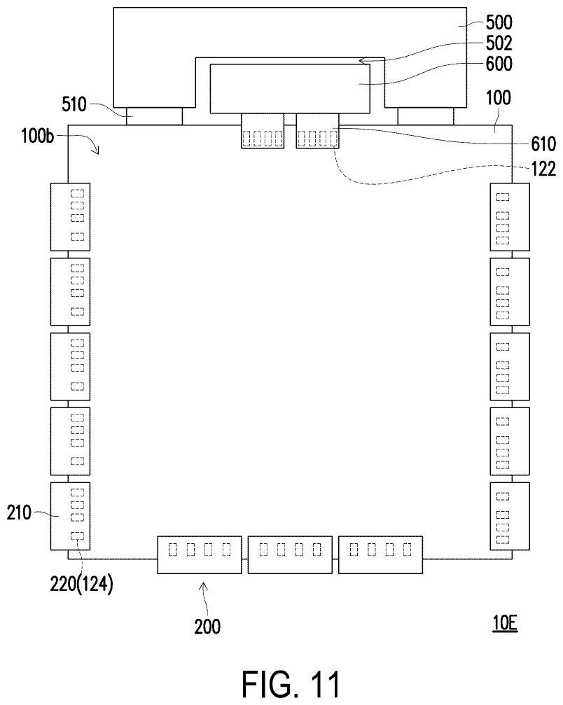

FIG. 11 is a schematic bottom view of a display panel 10E according to yet another embodiment of the invention. It should be noted herein that, in embodiments provided in FIG. 11, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 11, to prevent contact between the first system board 500 and the second system board 600, a groove 502 corresponding to the second system board 600 is formed on the first system board 500. Therefore, the first system board 500 does not overlap with the second system board 600 in the normal direction of the first surface and the second surface of the first substrate 100.

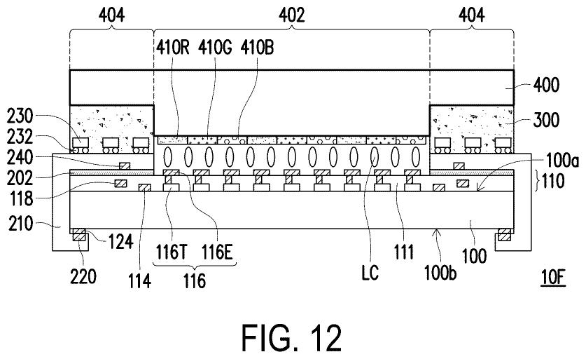

FIG. 12 is a schematic cross-sectional view of a display panel 10F according to another embodiment of the invention. It should be noted herein that, in embodiments provided in FIG. 12, element numerals and partial content of the embodiments provided in FIG. 5A and FIG. 5B are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 12, in this embodiment, part of the first signal lines 114 in the first circuit structure 110 are located between the flexible circuit board 210 and the first surface 100a of the first substrate 100. The first signal lines 114 are electrically connected to the first bonding pads (referring to FIG. 1A) and/or the pixel structure 116. Through this arrangement, the circuit layout space may be utilized more effectively, reducing the interference of the first signal lines 114 on the display image.

What is claimed is:

1. A display panel, comprising:
a first substrate, having a first surface and a second surface opposite to the first surface;
a first circuit structure, disposed on the first surface of the first substrate;
a second circuit structure, disposed on the second surface of the first substrate;
a liquid crystal layer, located on the first circuit structure;
a light-emitting diode module (LED module), comprising:
a flexible circuit board, connected to the second circuit structure, and bent from the second surface of the first substrate to above the first surface of the first substrate; and
a light-emitting diode (LED), disposed on the flexible circuit board located above the first surface of the first substrate, and electrically connected to the flexible circuit board;
a sealant layer, surrounding the liquid crystal layer, and covering the LED;
a second substrate, overlapping the first substrate, and the first circuit structure, the sealant layer, the liquid crystal layer and the LED are located between the first substrate and the second substrate.

2. The display panel of claim 1, further comprising:
a plurality of LED modules, wherein each of the plurality of LED modules comprises:
a corresponding one flexible circuit board, connected to the second circuit structure, and bent from the second surface of the first substrate to the first surface of the first substrate; and
corresponding plurality of LEDs, disposed on the corresponding one flexible circuit board located on the first surface of the first substrate, and electrically connected to the corresponding one flexible circuit board.

3. The display panel of claim 2, wherein each of the plurality of LED modules further comprises:
a micro integrated circuit, bonded to the corresponding one flexible circuit board, wherein the second circuit structure comprises:
a plurality of connection pads, bonded to the plurality of LED modules; and
a plurality of connection lines, each of the plurality of connection lines electrically connecting corresponding two adjacent ones of the plurality of LED modules.

4. The display panel of claim 1, wherein the second substrate comprises:
a liquid crystal area, overlapping the liquid crystal layer; and
an LED area, overlapping the LED, wherein the thickness of the LED area is less than the thickness of the liquid crystal area.

5. The display panel of claim 1, further comprising:
an adhesive layer, located between the flexible circuit board and the first surface of the first substrate.

6. The display panel of claim 1, further comprising:
a height augmentation layer, located between the first substrate and the second substrate, and overlapping the liquid crystal layer in a normal direction of the first surface, wherein the height augmentation layer does not overlap the LED in the normal direction of the first surface.

7. The display panel of claim 1, wherein the LED is bonded to the flexible circuit board through a conductive connection structure.

8. The display panel of claim 1, wherein the first circuit structure comprises a plurality of first bonding pads and a plurality of pixel structures, wherein the plurality of pixel structures overlap the liquid crystal layer, and wherein a first system board is electrically connected to the plurality of first bonding pads, and electrically connected to the plurality of pixel structures through the plurality of first bonding pads.

9. The display panel of claim 8, wherein the second circuit structure comprises:
a plurality of second bonding pads, wherein a second system board is electrically connected to the plurality of second bonding pads, and the plurality of first bonding pads and the plurality of second bonding pads are respectively located on the first surface and the second surface of the first substrate;
a plurality of connection pads, wherein the LED module is bonded to at least part of the plurality of connection pads; and
a plurality of signal lines, electrically connecting the plurality of second bonding pads and the plurality of connection pads.

10. The display panel of claim 9, wherein the first system board has a recess corresponding to the second system board, and the first system board does not overlap the second system board in a normal direction of the first surface.

11. The display panel of claim 1, wherein the first circuit structure comprises a plurality of pixel structures, wherein the plurality of pixel structures overlap the liquid crystal layer, and the LED module comprises a plurality of LEDs, wherein a pitch between adjacent ones of the plurality of pixel structures is equal to a pitch between adjacent ones of the plurality of LEDs.

12. The display panel as of claim 1, further comprising:
a first alignment mark, disposed on the first surface of the first substrate, and adjacent to a second alignment mark in the LED module.

13. The display panel of claim 1, wherein part of the flexible circuit board is located between the first substrate and the second substrate.

14. The display panel of claim 1, wherein the first circuit structure further comprises:
a first signal line, partially located between the flexible circuit board and the first surface.
